(19) United States
(12) Patent Application Publication
(10) Pub. No.: US 2024/0224595 A1
(43) Pub. Date: Jul. 4, 2024

(54) THIN FILM TRANSISTOR ARRAY SUBSTRATE INCLUDING OXIDE SEMICONDUCTOR PATTERN AND DISPLAY APPARATUS INCLUDING THEREOF

(71) Applicant: LG DISPLAY CO., LTD., Seoul (KR)

(72) Inventors: Duk-Young JEONG, Paju-si (KR); Won-Hoon PARK, Paju-si (KR)

(73) Assignee: LG DISPLAY CO., LTD., Seoul (KR)

(21) Appl. No.: 18/522,188

(22) Filed: Nov. 28, 2023

(30) Foreign Application Priority Data
Jan. 2, 2023 (KR) 10-2023-0000211

(51) Int. Cl. H10K 59/121; H10K 59/126

(52) U.S. Cl. CPC H10K 59/1213; H10K 59/126

(57) ABSTRACT

A thin film transistor array substrate according to the present disclosure includes a substrate including a display area and a non-display area around the display area, a plurality of pixels in the display area, a first thin film transistor disposed in each pixel, wherein the first thin film transistor includes a first oxide semiconductor pattern, a first gate electrode overlapped with the first oxide semiconductor pattern, a first lower conductive pattern facing the first gate electrode with the first oxide semiconductor pattern interposed therebetween, a first source electrode and a first drain electrode connected to the first oxide semiconductor patter, respectively, and an electric field shielding pattern between the first oxide semiconductor pattern and the first lower conductive pattern.

### CROSS-REFERENCE TO RELATED APPLICATIONS

This application claims priority to and the benefit of Republic of Korea Patent Application No. 10-2023-0000211, filed on Jan. 2, 2023, the disclosure of which is incorporated herein by reference in its entirety.

### BACKGROUND

### 1. Technical Field

The present disclosure relates to an array substrate of thin film transistor including an oxide semiconductor pattern and a display apparatus capable of displaying an image having, blocking leakage current, and increasing threshold voltage.

### 2. Discussion of the Related Art

Recently, the importance of flat panel display apparatus is increasing as multimedia is developed. Accordingly, the flat panel apparatus such as a liquid crystal display apparatus, a plasma display apparatus, and an organic light emitting display apparatus is commercialized. Among these flat panel display apparatuses, the organic light emitting display apparatus are currently widely used because it has a high response speed, a high brightness, and a wide viewing angle.

In the organic light emitting display apparatus, a plurality of pixels are arranged in a matrix shape. In each pixel, a light-emitting device part including an organic light-emitting layer and a pixel circuit part including a thin film transistor are disposed. The pixel circuit part includes a driving thin film transistor (driving TFT) for supplying driving current to operate the organic light emitting device and a switching thin film transistor (switching TFT) for supplying a gate signal to the driving thin film transistor.

Further, a gate driving circuit unit for supplying a gate signal to the pixel may be disposed in a non-display area of the organic light emitting display apparatus.

As such, the present disclosure relates to the array substrate disposed in the pixel circuit part of the sub-pixel and including the thin film transistor of which the leakage current can be blocked in an off state and the gradation expression can be free at low gradations and to the display apparatus having thereof.

### SUMMARY

Accordingly, embodiments of the present disclosure are directed to a thin film transistor array substrate including an oxide semiconductor pattern and a display apparatus including thereof that substantially obviates one or more of the problems due to limitations and disadvantages of the related art.

An aspect of the present disclosure is to provide a array substrate and a display apparatus having an oxide semiconductor pattern of a high S-factor in which the leakage current may be blocked in the off state and the gradation expression can be free at the low gradations.

Another aspect of the present disclosure is to provide a switching thin film transistor capable of minimizing the effect by an electric field to solve the problem of reliability damage in which the threshold voltage moves due to continuous application of voltage among a plurality of switching thin film transistors disposed in a sub-pixel.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor array substrate comprises a substrate including a display area and a non-display area around the display area, a plurality of pixels in the display area, a first thin film transistor disposed in each pixel, wherein the first thin film transistor includes a first oxide semiconductor pattern, a first gate electrode overlapped with the first oxide semiconductor pattern, a first lower conductive pattern facing the first gate electrode with the first oxide semiconductor pattern interposed therebetween, a first source electrode and a first drain electrode connected to the first oxide semiconductor patter, respectively, and an electric field shielding pattern between the first oxide semiconductor pattern and the first lower conductive pattern.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic block diagram of a display apparatus according to the present disclosure.

FIG. 2 is the schematic block diagram of a sub-pixel of the display apparatus according to present disclosure.

FIG. 3 is a circuit diagram of the sub-pixel of the display apparatus according to present disclosure.

FIG. 4A is the cross-sectional view of one thin film transistor in a gate driving circuit unit of the non-display area, a driving thin film transistor in a display area, a switching thin film transistor in the display area, and a storage capacitor in the display area according to an embodiment of the present disclosure.

FIG. 4B is the cross-sectional view showing parasitic capacitance generated inside the driving thin film transistor of the present disclosure.

FIG. 4C is the circuit diagram showing the relationship between parasitic capacitances shown in FIG. 4B.

FIG. 5 is an enlarged cross-sectional view of only the driving thin film transistor and the switching thin film transistor of FIG. 4A.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

Each feature of the various embodiments of the present disclosure can be partially or fully combined or combined with each other, various technological interconnections and operations are possible, and each embodiment can be implemented independently of each other or together in a related relationship.

Hereinafter, the first embodiment of the present disclosure will be described in detail with reference to the accompanying drawings.

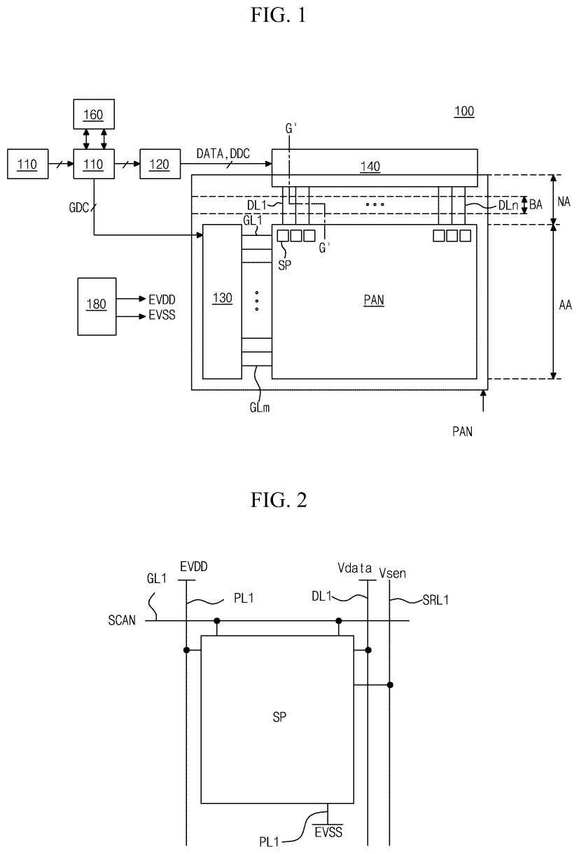

FIG. 1 is the schematic block diagram of the display apparatus 100 according to the present disclosure.

FIG. 2 is the schematic block diagram of the sub-pixel of the display apparatus according to present disclosure.

As shown in FIG. 1, the display apparatus 100 includes a display panel PAN in which an image processing unit 110, a deterioration compensation unit 150, a memory 160, a timing control unit 120, a data driving unit 140, a power supply unit 180, and a gate driving unit 130 are formed. In particular, the non-display area NA of the display panel PAN includes a bending area BA. The bending area BA of the display panel PAN can be folded to reduce the bezel of the display apparatus 100.

The image processing unit 110 outputs image data supplied from the outside and driving signals for driving various devices.

The deterioration compensation unit 150 modulates the input image data Idata of each sub-pixel SP at the current frame based on the sensing voltage Vsen supplied from the data driving unit 140 and then supplies the modulated data Mdata to the timing control unit 120.

The timing controlling unit 120 generates and outputs gate timing controlling signal GDC for controlling the driving timing of the gate driving unit 130 and data timing controlling signal DDC for controlling the driving timing of the data driving unit 140 based on the driving signal from the image processing unit 110.

The gate driving unit 130 outputs the scan signal to the display panel PAN in response to the gate timing control signal GDC supplied from the timing controlling unit 120. The gate driving unit 130 outputs the scan signal through a plurality of gate lines GL1 to GLm. In particular, gate driving unit 130 may be formed in the GIP (Gate In Panel) structure in which the thin film transistors are directly formed on the substrate 110 of the organic light emitting display apparatus. The GIP may include the various circuits such as a shift register and a level shifter.

The data driving unit 140 outputs the data voltage to the display panel PAN in response to the data timing control signal DDC input from the timing controlling unit 120. The data driving unit 140 outputs the data voltage through the plurality of data lines DL1 to DLn.

The power supply unit 180 outputs a high potential voltage EVDD and a low potential voltage EVSS etc. The high potential voltage EVDD and the low potential voltage EVSS are supplied to the display panel PAN through a power line.

The display panel PAN displays the images in response to the data voltage and scan signal supplied from the data driving unit 140 and the gate driving unit 130 in the non-display area NA, and the power supplied from the power supply unit 180 in the non-display area NA. The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

A look-up table for the degradation compensation gain and the degradation compensation timing of the organic light emitting device of the sub-pixel SP are stored in a memory 160. At this time, the degradation compensation timing of the organic light emitting device may be the driving number or driving time of the organic light emitting display panel.

Meanwhile, as shown in FIG. 2, one sub-pixel SP can be connected to a gate line GL1, a data line DL1, a sensing voltage read out line SRL1, and a power line PL1. Depending on the configuration of the circuit of the sub-pixel SP, the number of transistors, the number of capacitors, and the driving method are determined.

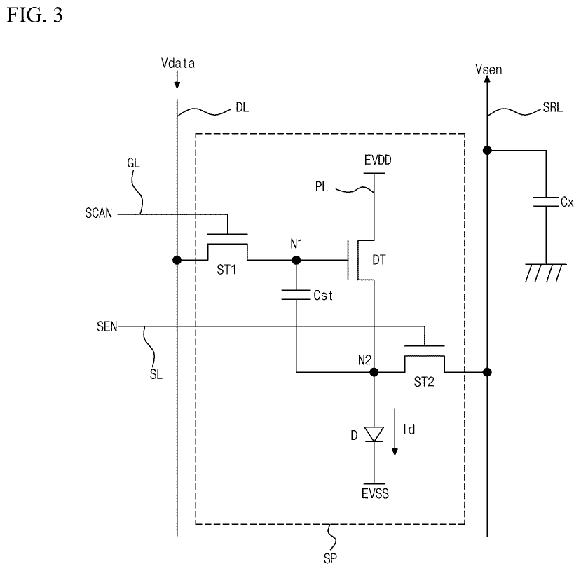

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL, and a sensing line SL which are crossing each other for defining the sub-pixel SP. In the sub-pixel, the driving thin film transistor DT, the light emitting device D, a storage capacitor Cst, a first switching thin film transistor ST1, and a second switching thin film transistor ST2 are disposed.

The light emitting device D may include an anode electrode connected to a second node N2, a cathode electrode connected to an input terminal of a low potential driving voltage EVSS, and an organic light emitting layer between the anode electrode and the cathode electrode.

The driving thin film transistor DT controls the current Id flowing through the light emitting device D according to a gate-source voltage Vgs. The driving thin film transistor DT includes the gate electrode connected to the first node N1, the drain electrode connected to the power line PL to provide a high potential driving voltage EVDD, and a source electrode connected to the second node N2.

The storage capacitor Cst is connected between the first node N1 and the second node N2.

The first switching thin film transistor ST1 supplies the data voltage Vdata charged in the data line DL to the first node in response to the gate signal SCAN when driving the display panel PAN to turn on the driving transistor DT. At this time, the first switching thin film transistor ST1 includes the gate electrode connected to the gate line GL to which the scan signal SCAN is input, the drain electrode connected to the data line DL to which the data voltage Vdata is input, and the source electrode connected to the first node N1. The first switching thin film transistor ST1 is known to operate more sensitively than other switching thin film transistors in the sub-pixel. Therefore, the first switching thin film transistor ST1 needs to be easily controlled by increasing its threshold voltage.

The second switching thin film transistor ST2 switches the current between the second node N2 and the sensing voltage lead out line SRL in response to the sensing signal SEN to store the source voltage of the second node N2 in the sensing capacitor Cx of the voltage sensing lead out line SRL. The second switching thin film transistor ST2 switches the current between the second node N2 and the sensing voltage lead out line SRL in response to the sensing signal SEN when driving the display panel PAN to reset the source voltage of the driving thin film transistor DT into an initialization voltage Vpre. At this time, the gate electrode of the second switching thin film transistor ST2 is connected to the sensing line SL, the drain electrode of the second switching thin film transistor ST2 is connected to the second node N2, and the source electrode of the second switching thin film transistor ST2 is connected to the sensing voltage lead out line SRL.

In the figure, only three thin film transistors and one capacitor are provided, but the present disclosure is not limited thereto. Three or more thin film transistors and two or more capacitors may be provided in the present invention.

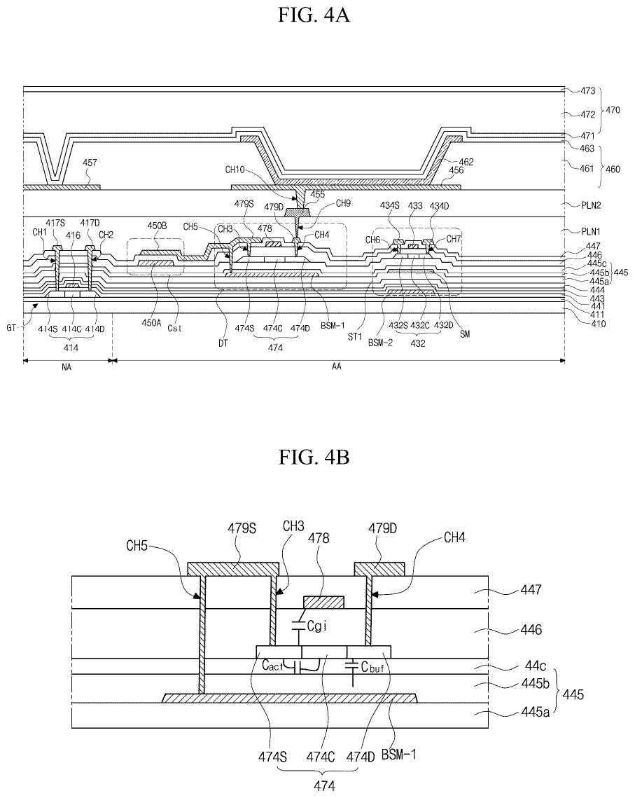

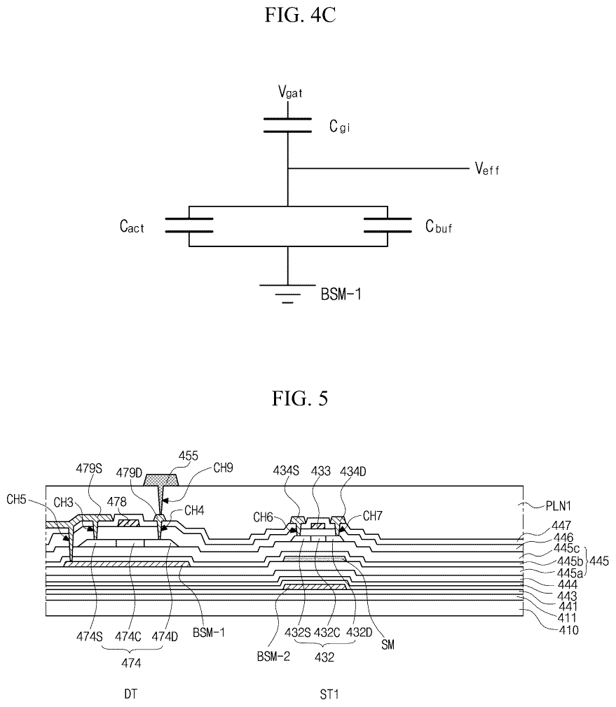

Meanwhile, FIG. 4A is the cross sectional view showing the gate driving thin film transistor GT including a polycrystalline semiconductor pattern in the GIP area, the driving thin film transistor DT for driving the light emitting device, which includes an oxide semiconductor pattern, in the sub-pixel, the first switching thin film transistor ST1, and the storage capacitor Cst.

Referring to FIG. 4A, the driving thin film transistor DT and the first switching thin film transistor ST1 are disposed in the sub-pixel on the substrate 410. At this time, FIG. 4A shows only the driving thin film transistor DT and one switching thin film transistor ST1, but this is only for convenience of explanation, and in reality multiple switching thin film transistors may be disposed on the substrate 410.

Further, a plurality of gate driving thin film transistors GT included in the gate driving unit may be disposed in the non-display area NA, specially in the GIP area, on the substrate 410. The active layer of the gate driving thin film transistor GT may be formed of the polycrystalline semiconductor pattern. However, this is only an example, and the active layer of the gate driving thin film transistor GT may be formed of the oxide semiconductor material as the first switching thin film transistor ST1.

In addition, the structure in which the gate driving thin film transistor GT having the polycrystalline semiconductor material is disposed in the non-display area NA is described in the first embodiment, but the switching thin film transistor having the same structure as the gate driving thin film transistor GT may be disposed in the sub-pixel of the display area.

In other words, the gate driving thin film transistor GT in the non-display area NA and the switching thin film transistor in the display area AA may have the same structure, but since the types of impurities doped for each are different, they can be driven as the thin film transistors having different characteristics such as N-TYPE thin film transistor and a P-TYPE thin film transistor.

Meanwhile, each of the plurality of thin film transistors in the gate driving unit may be composed of CMOS transistor including the thin film transistor having the polycrystalline semiconductor and the thin film transistor having the oxide semiconductor.

Hereinafter, the gate driving thin film transistor having the polycrystalline semiconductor will be described as an example disposed in the non-display area NA.

The gate driving thin film transistor GT includes the polycrystalline semiconductor pattern 414 disposed on a lower buffer layer 411 on the substrate 410, a first gate insulating layer 442 for insulating the polycrystalline semiconductor pattern 414, a first gate electrode 416 overlapped with the polycrystalline semiconductor pattern 414 on the first gate insulating layer 442, a plurality of insulating layers, and a first source electrode 417S and a first drain electrode 417D on the plurality of insulating layers.

The substrate 410 may be formed of multi layers in which organic layers and inorganic layers are alternately deposited. For example, the organic layers made of polyimide and the inorganic layers made of SiO2 are alternately deposited to form the substrate 410.

The lower buffer layer 411 is formed on the substrate 410. The lower buffer layer 411 protects the lower buffer layer 411 block moistures from the outside, and can be formed by depositing at least one inorganic insulating layer such as a SiO2 film.

The polycrystalline semiconductor pattern 414 is formed on the lower buffer layer 411. The polycrystalline semiconductor pattern 414 is the active layer of the thin film transistor. The polycrystalline semiconductor pattern 414 includes a first channel region 414C, a first source region 414S and a first drain region 414D facing each other at both sides of first channel region 414C.

The polycrystalline semiconductor pattern 414 is insulated by the first gate insulating layer 442. The first gate insulating layer 442 is formed by depositing at least one inorganic insulating layer such as SiO2 over the entire substrate 410 on which the polycrystalline semiconductor pattern 414 is formed. The first gate insulating layer 442 protects and insulates the polycrystalline semiconductor pattern 414 from the outside.

A first gate electrode 416 is formed on the first gate insulating layer 442 and overlapped with the first channel region 414C of the polycrystalline semiconductor pattern 414.

The first gate electrode 416 may be made of a metal material. For example, the first gate electrode 416 is formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

A plurality of insulating layers may be formed between the first gate electrodes 416 and the first source and drain electrodes 417S and 417D.

Referring to FIG. 4A, the plurality of insulating layers include a first interlayer insulating layer 443 contacted with the upper surface of the first gate electrode 416, a second interlayer insulating layer 444 sequentially deposited on the first interlayer insulating layer 443, an upper buffer layer 445, a second gate insulating layer 446, and a third interlayer insulating layer 447.

The first source electrode 417S and the first drain electrode 417D are disposed on the third interlayer insulating layer 447. The first source electrode 417S and the first drain electrode 417D are connected to the polycrystalline semiconductor pattern 414 through the first contact hole CH1 and the second contact hole CH2, respectively. The first contact hole CH1 and the second contact hole CH2 are formed in the first gate insulating layer 442, the first interlayer insulating layer 443, the second interlayer insulating layer 444, the upper buffer layer 445, the second gate insulating layer 446, and third interlayer insulating layer 447 to expose the first source region 414S and the first drain region 414D to the outside.

The driving thin film transistor DT, the first switching thin film transistor ST1, and the storage capacitor Cst are disposed in the sub-pixel of the display area AA.

In the first embodiment, the active layer of the driving thin film transistor DT and the first switching thin film transistor ST1 is made of the oxide semiconductor pattern.

The driving thin film transistor DT includes the first oxide semiconductor pattern 474, the second gate electrode 478 overlapped with the first oxide semiconductor pattern 474, the second source electrode 479S, and the second drain electrode 479D.

The oxide semiconductors may be formed of a metal oxide of metals such as Zn, In, Ga, Sn, and Ti and may be formed of an alloy of this metal oxide and this metal. For example, oxide semiconductors may include ZnO, ZTO, ZIO, InO, TIO, IGZO, IZTO, etc.

Generally, the polycrystalline semiconductor pattern that is advantageous for high-speed operation is used as the active layer of the driving thin film transistor. However, the driving thin film transistor including the polycrystalline semiconductor pattern has the problem in that the current is leaked in an off state and thus power consumption is increased. In particular, the leakage current in the off state becomes a major problem when the display apparatus is driven at low speeds to display still images such as document screens. Accordingly, in the first embodiment of the present disclosure, the leakage current is prevented by using a driving thin film transistor having the oxide semiconductor pattern as the active layer.

However, when the active layer of the thin film transistor is the oxide semiconductor pattern, the current fluctuation value relative to the voltage fluctuation value is large due to the material characteristics of the oxide semiconductor, so the defects may generate in low gray level areas that require precise current control. Accordingly, in the first embodiment, the structure of a driving thin film transistor in which the current change value is relatively insensitive to the change value of the voltage applied to the gate electrode is proposed.

The structure of the driving thin film transistor will be described with reference to FIGS. 4A to 5. FIG. 4B is the enlarged cross-sectional view of only the driving thin film transistor DT in FIG. 4A, and FIG. 4C is the circuit diagram showing the relationship between parasitic capacitances generated inside the driving thin film transistor DT. FIG. 5 is the enlarged cross-sectional view of only the driving thin film transistor DT and the first switching thin film transistor ST1 in FIG. 4A.

The driving thin film transistor DT includes the first oxide semiconductor pattern 474 on the upper buffer layer 445, the second gate insulating layer 446 covering the first oxide semiconductor pattern 474, and the second gate electrode 478 overlapped with the first oxide semiconductor pattern 474 on the second gate insulating layer 446, and the second source electrode 479S and the second drain electrode 479D on the third interlayer insulating layer 447 covering the second gate electrode 478. The second gate electrode 478, the second source electrode 479S, and the second drain electrode 479D can be disposed on the same layer.

The first oxide semiconductor pattern 474 which is the active layer includes a second channel region 474C for moving the charges, a second source region 474S and a second drain region 474D facing each other at both sides of second channel region 474C.

A first lower conductive pattern BSM-1 is formed below the first oxide semiconductor pattern 474. The first lower conductive pattern BSM-1 blocks the light incident from the outside into the first oxide semiconductor pattern 474 and prevents malfunction of the first oxide semiconductor pattern 474 due to external light. Further, the first lower conductive pattern BSM-1 collects hydrogen particles into the first oxide semiconductor pattern 474 from the bottom and prevents the damage of the first oxide semiconductor pattern 474 caused by the hydrogen particles. Therefore, the first lower conductive pattern BSM-1 may be made of the metal layer containing titanium (Ti) material that can trap hydrogen particles. For example, the first lower conductive pattern BSM-1 may be formed of a single metal layer of titanium or a multi-layer metal layer of molybdenum (Mo) and titanium (Ti). Further, the first lower conductive pattern BSM-1 may be made of an alloy of molybdenum (Mo) and titanium (Ti). However, it is not limited to this material and other metal layers including titanium (Ti) are also possible.

Titanium (Ti) can trap hydrogen particles diffusing into the upper buffer layer 445 and block the hydrogen particles penetrating to the first oxide semiconductor pattern 474.

The first lower conductive pattern BSM-1 is preferably formed vertically below the first oxide semiconductor pattern 474 so that the first lower conductive pattern BSM-1 is overlapped with the first oxide semiconductor pattern 474. Further, the first lower conductive pattern BSM-1 may be larger than the first oxide semiconductor pattern 474 so that the first lower conductive pattern BSM-1 is completely overlapped with the first oxide semiconductor pattern 474.

Meanwhile, the second source electrode 479S of the driving thin film transistor DT is electrically connected to the first lower conductive pattern BSM-1. By electrically connecting the first lower conductive pattern BSM-1 to the second source electrode 479S, the following additional effects can be obtained.

As each of the second source region 474S and the second drain region 474D of the first oxide semiconductor pattern 474 are conductive, the parasitic capacitance Cact is generated inside the first oxide semiconductor pattern 474 during on/off operation. Further, the parasitic capacitance Cgi is generated between the second gate electrode 478 and the first oxide semiconductor pattern 474. The parasitic capacitance Cbuf is generated between the first lower conductive pattern BSM-1 connected electrically to the second source electrode 479S and the first oxide semiconductor pattern 474.

Since the first oxide semiconductor pattern 474 and the first lower conductive pattern BSM-1 are electrically connected by the second source electrode 479S, the parasitic capacitance Cact and the parasitic capacitance Cbuf are connected in parallel, and the parasitic capacitance Cact and the parasitic capacitance Cgi are connected in series. When the gate voltage of Vgat is applied to the second gate electrode 478, the effective voltage Veff actually applied to the first oxide semiconductor pattern 474 is determined by equation 1 below.

$$ΔV eff = \frac{Cgi}{Cgi + Cbuf + Cact} * ΔV gat \qquad [ equation 1 ]$$

Therefore, since the effective voltage Veff applied to the second channel region 474C is inversely proportional to the parasitic capacitance Cbuf, the effective voltage applied to the first oxide semiconductor pattern 474 can be controlled by adjusting the parasitic capacitance Cbuf. That is, when the parasitic capacitance Cbuf is increased by positing the first lower conductive pattern BSM-1 close to the first oxide semiconductor pattern 474, the actual current value flowing through the first oxide semiconductor pattern 474 can be reduced.

The decrease of the effective current flowing through the first oxide semiconductor pattern 474 means that the s-factor is increased. This means that the control range of the driving thin film transistor DT that can be controlled through the voltage Vgat applied to the second gate electrode 478 is expanded.

That is, when the second source electrode 479S of the driving thin film transistor DT is electrically connected to the first lower conductive pattern BSM-1 and the first lower conductive pattern BSM-1 is disposed close to the first oxide semiconductor pattern 474, the organic light emitting device can be controlled precisely even at low gray levels and thus the problem of the screen stains that often occur in low gray level can be solved.

Accordingly, in the first embodiment of the present disclosure, the parasitic capacitance Cbuf between the first oxide semiconductor pattern 474 and the first lower conductive pattern BSM-1 may be larger than the parasitic capacitance Cgi between the second gate electrode 478 and the first oxide semiconductor pattern 474.

Here, the s-factor is the reciprocal value of the amount of current change relative to the amount of change in gate voltage in the on/off transition interval of the thin film transistor. In other words, the s-factor may be the reciprocal value of the slope of the curve in the characteristic graph of the drain current versus the gate voltage (V-I curve graph).

The small s-factor means that the slope of the characteristic graph of drain current versus gate voltage is large, so that the thin film transistor is turned on even by the small voltage. Therefore, the switching characteristics of the thin film transistor improve. On the other hand, since the voltage reaches the threshold voltage in a short time, it is difficult to express sufficient grayscale.

The large s-factor means that the slope of the characteristic graph of drain current versus gate voltage is small, so that the on/off reaction speed of the thin film transistor is decreased. Therefore, the switching characteristic of the thin film transistor is deteriorated. On the other hand, since the voltage reaches the threshold voltage for a relatively long time, sufficient grayscale expression is possible.

In particular, the first lower pattern BMS-1 may be placed close to the first oxide semiconductor pattern 474 by being inserted into the upper buffer layer 445. That is, the vertical distance between the first oxide semiconductor pattern 474 and the first lower conductive pattern BSM-1 is shorter than the vertical distance between the first oxide semiconductor pattern 474 and the second gate electrode 478, so that the s-factor of the driving thin film transistor DT can be increased.

The first lower conductive pattern BSM-1 is preferably formed vertically below the first oxide semiconductor pattern 474 so that the first lower conductive pattern BSM-1 is overlapped with the first oxide semiconductor pattern 474. Further, the first lower conductive pattern BSM-1 may be larger than the first oxide semiconductor pattern 474 so that the first lower conductive pattern BSM-1 is completely overlapped with the first oxide semiconductor pattern 474.

Meanwhile, the second gate electrode 478 of the driving thin film transistor DT is insulated by the third interlayer insulating layer 447, and the second source electrode 479S and the second drain electrode 479D are formed on the third interlayer insulating layer 447.

In FIG. 4A, the second source electrode 479S and the second drain electrode 479D are disposed on the same layer and the second gate electrode 478 is formed on the different layer from the second source electrode 479S and the second drain electrode 479D. However, the second gate electrode 478, the second source electrode 479S, and the second drain electrode 479D may be disposed on the same layer.

The second source electrode 479S and the second drain electrode 479D are respectively connected to the second source region 474S and the second drain region 474D through the third contact hole CH3 and the fourth contact hole CH4. Further, the first lower conductive pattern BSM-1 is connected to the second source electrode 479S through the fifth contact hole CH5.

Meanwhile, the first switching thin film transistor ST1 includes the second oxide semiconductor pattern 432, the third gate electrode 433, the third source electrode 434S, and the third drain electrode 434D.

The second oxide semiconductor pattern 432 includes the third channel region 432C, the third source region 432S and the third drain region 432D facing each other at both sides of the third channel region 432C.

The third gate electrode 433 is disposed on the second oxide semiconductor pattern 432 with the second gate insulating layer 446 interposed therebetween.

The third source electrode 434S and the third drain electrode 434D may be disposed on the same layer as the second source electrode 479S and the second drain electrode 479D. That is, the second source electrode 479S, the second drain electrode 479D, the third source electrode 434S, and the third drain electrode 434D may be disposed on the third interlayer insulating layer 447.

However, the third source electrode 434S and the third drain electrode 434D may be disposed on the same layer as the third gate electrode 433. That is, the third source electrode 434S and the third drain electrode 434D may be simultaneously formed with the same material on the second gate insulating layer 446.

Further, a second lower conductive pattern BSM-2 may be disposed below the second oxide semiconductor pattern 432.

The second lower conductive pattern BSM-2 may be electrically connected to the third gate electrode 433 to form a dual gate.

When the first switching thin film transistor ST1 is a sampling transistor connected to the gate node of the driving thin film transistor DT, the first switching thin film transistor ST1 is turned on only for a very short time by applying the positive voltage and turned off for the rest of the time by applying the negative voltage. That is, the first switching thin film transistor ST1 is turned on once and turned off for the rest of the time during one frame. Accordingly, the first switching thin film transistor ST1 turned off by the negative voltage is placed in a negative bias temperature stress (NBTS) state and thus the thin film transistor is deteriorated. Accordingly, in the present disclosure, an electric field shielding pattern SM is disposed between the second oxide semiconductor pattern 432 and the second lower conductive pattern BSM-2 to block the electric field, so that the deterioration of the first switching thin film transistor ST1 can be prevented.

The first switching thin film transistor ST1 has the dual gate structure to operate at high speed. Since the first switching thin film transistor ST1 has the dual gate, the stronger electric field can be applied to the active layer, and as a result the first switching thin film transistor ST1 can operate at high speed. However, since the first switching thin film transistor ST1 is turned on only once and receives the negative voltage for the remaining time during one frame, the switching device is deteriorated. However, in the present disclosure, since the first switching thin film transistor ST1 includes the electric field shielding pattern SM, it is possible to prevent the first switching thin film transistor ST1, which operates at high speed, from being deteriorated by negative voltage.

The electric field shielding pattern SM is disposed between the second lower conductive pattern BSM-2 and the second oxide semiconductor pattern 432 forming the dual gate. Accordingly, the electric field shielding pattern SM can prevent the deterioration of the second oxide semiconductor pattern 432 by shielding the electric field applied from the second lower conductive pattern BSM-2 to the second oxide semiconductor pattern 432. Here, the deterioration means that the threshold voltage of the first switching thin film transistor ST1 moves to the negative value as the usage time of the first switching thin film transistor ST1 is increased. This damages the reliability of the first switching thin film transistor ST1.

Since the purpose of the electric field shielding pattern SM is to shield the electric field generated from the second lower conductive pattern BSM-2, the electric field shielding pattern SM is preferably in a floating state.

Referring to FIG. 5, in the present disclosure, the electric field shielding pattern SM is formed of the same material on the same layer as the first lower conductive pattern BSM-1, thereby reducing the process.

However, the location of the electric field shielding pattern SM is not limited to the embodiment disclosed in FIG. 5.

That is, the electric field shielding pattern SM may control the strength of the electric field generated from the second lower conductive pattern BSM-2 by adjusting the position of the electric field shielding pattern SM.

When the electric field shielding pattern SM is disposed closer to the second lower conductive pattern BSM-2, the electric field shielding pattern SM can more strongly shield the electric field generated by the second lower conductive pattern BSM-2. On the other hand, when the electric field shielding pattern SM is disposed away from the second lower conductive pattern BSM-2 and closer to the second oxide semiconductor pattern 432, the electric field shielding effect of the electric field shielding pattern SM may be reduced. It is also possible to adjust the threshold voltage of the first switching thin film transistor ST1 by varying the shielding strength of the electric field shielding pattern SM.

Meanwhile, referring to FIG. 4A, the sub-pixel includes the storage capacitor Cst.

The storage capacitor Cst stores the data voltage applied through the data line for a certain period of time and supplies it to the organic light emitting device.

The storage capacitor Cst includes two electrodes corresponding to each other and a dielectric disposed between them. The storage capacitor Cst includes a first storage capacitor electrode 450A disposed on the substrate 410 and a second storage capacitor electrode 450B that overlaps and faces the first storage capacitor electrode 450A.

At least one insulating layer may be interposed between the first storage capacitor electrode 450A and the second storage capacitor electrode 450B.

The second storage capacitor electrode 450B may be electrically connected to the second source electrode 479S.

Meanwhile, referring to FIG. 4A, a first planarization layer PLN1 may be formed on the substrate 410 on which the driving thin film transistor DT and the first switching thin film transistor ST1 are disposed. The first planarization layer PLN1 may be formed of the organic material such as photo acrylic, but may also be formed of the plurality of layers including the inorganic layer and the organic layer. A connection electrode 445 is formed on the first planarization layer PLN1. The connection electrode 445 electrically connects the anode electrode 456 of the light emitting device 460 and the driving thin film transistor DT to each other through the ninth contact hole CH9 formed in the first planarization layer PLN1.

Further, the conductive layer forming the connection electrode 455 may be a part of various link lines disposed in the bending area BA.

A second planarization layer PLN2 may be formed on the connection electrode 455. The second planarization layer PLN2 may be formed of the organic material such as photo acrylic like the first planarization layer PLN1, but may also be formed of the plurality of layers including the inorganic layer and the organic layer.

An anode electrode 456 is formed on the second planarization layer PLN2. The anode electrode 456 is electrically connected to the connection electrode 455 through the tenth contact hole CH10 formed in the second planarization layer PLN2.

The anode electrode 456 is formed of the single layer or the multiple layers made of metals such as Ca, Ba, Mg, Al, Ag, etc. or alloys thereof, and is connected to the second drain electrode 479D of the driving thin film transistor DT so that the image signal is applied to the anode electrode 456 from outside.

An anode connection electrode 457 for connecting the common voltage line VSS and the cathode electrode 463 may be disposed in the non-display area NA.

A bank layer 461 is formed on the second planarization layer PLN2. The bank layer 461 partitions each sub-pixel to prevent mixing of light of a specific color output from adjacent sub-pixels.

The organic light emitting layer 462 is formed on the upper surface of the anode electrode 456 and the inclined surface of the bank layer 461. The organic light emitting layer 462 is formed in the R, G, and B sub-pixels and may include an R-organic light emitting layer for emitting red light, a G-organic light emitting layer for emitting green light, and a B-organic light emitting layer for emitting blue light. Further, the organic layer 462 may include a W organic light emitting layer for emitting white light.

The organic light emitting layer 462 may further include an electron injecting layer for injecting electrons into the light emitting layer, a hole injecting layer for injecting holes into the light emitting layer, an electron transporting layer for transporting the injected electrons to the light emitting layer, and a hole transporting layer for transporting the injected holes to the light emitting layer, but is not limited thereto.

A cathode electrode 463 is formed on the organic light emitting layer 462. The cathode electrode 463 may be made of the transparent conductive material such as indium tin oxide (ITO) or indium zinc oxide (IZO), or the thin metal that transmits visible light, but is not limited thereto.

An encapsulation layer 470 is formed on the cathode electrode 463. The encapsulation layer 470 may be formed of the single layer made of the inorganic layer, may be formed of two layers of the inorganic layer/organic layer, or may be formed of three layers of the inorganic layer/organic layer/inorganic layer. The inorganic layer may be formed of the inorganic materials such as SiNx and SiX, but is not limited thereto. The organic layer may be formed of the organic materials such as polyethylene terephthalate, polyethylene naphthalate, polycarbonate, polyimide, polyethylene sulfonate, polyoxymethylene, and polyarylate, or a mixture thereof, but is not limited thereto.

In FIG. 4A, the encapsulation layer including the inorganic layer 471, the organic layer 472, and the inorganic layer 473 is disclosed as the example of the encapsulation layer.

Although not shown in figure, a cover glass may be attached to the encapsulation layer 470 using an adhesive layer. Any material can be used as the adhesive layer as long as it has good adhesion and good heat resistance and water resistance. In the present disclosure, a thermosetting resin such as an epoxy-based compound, an acrylate-based compound, or an acrylic rubber can be used. Further, a photocurable resin may be used as the adhesive, and in this case the adhesive layer is cured by irradiating light such as ultraviolet rays to the adhesive layer.

The adhesive layer not only bonds the substrate 410 and the cover glass (not shown), but also serves as a sealant to prevent moisture from penetrating into the organic light emitting display apparatus.

The cover glass (not shown) is an encapsulation cap for encapsulating the organic light emitting display apparatus, and formed of the protect film such as PS (Polystyrene) film, PE (Polyethylene) film, PEN (Polyethylene Naphthalate) film, or PI (Polyimide) film or formed of glass.

It will be apparent to those skilled in the art that various modifications and variations can be made in the thin film transistor array substrate including an oxide semiconductor pattern and the display apparatus including thereof of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor array substrate, comprising:
a substrate including a display area and a non-display area around the display area;
a plurality of pixels in the display area; and
a first thin film transistor disposed in each pixel,
wherein the first thin film transistor includes:
a first oxide semiconductor pattern;
a first gate electrode overlapped with the first oxide semiconductor pattern;
a first lower conductive pattern facing the first gate electrode with the first oxide semiconductor pattern interposed therebetween;
a first source electrode and a first drain electrode connected to the first oxide semiconductor pattern, respectively; and
an electric field shielding pattern between the first oxide semiconductor pattern and the first lower conductive pattern.

2. The thin film transistor array substrate of claim 1, further comprising a driving thin film transistor in each pixel,
Wherein the driving thin film transistor includes:
a second oxide semiconductor pattern on the substrate;
a second gate electrode overlapped with the second oxide semiconductor pattern;
a second source electrode and a second drain electrode connected to the second oxide semiconductor pattern, respectively; and
a second lower conductive pattern overlapped with the second oxide semiconductor pattern under the second oxide semiconductor pattern,
wherein the second lower conductive pattern is connected to one of the second source electrode and the second drain electrode.

3. The thin film transistor array substrate of claim 2, wherein the first thin film transistor is a switching thin film transistor connected to a gate node of the driving thin film transistor.

4. The thin film transistor array substrate of claim 1, wherein the electric field shielding pattern is floated.

5. The thin film transistor array substrate of claim 2, wherein the electric field shielding pattern is disposed on the same layer as the second lower conductive pattern.

6. The thin film transistor array substrate of claim 2, wherein a parasitic capacitance between the second oxide semiconductor pattern and the second lower conductive pattern is larger than that between the second oxide semiconductor pattern and the second gate electrode.

7. The thin film transistor array substrate of claim 1, wherein the first lower conductive pattern is electrically connected to the first gate electrode.

8. The thin film transistor array substrate of claim 1, wherein the first oxide semiconductor pattern, the first lower conductive pattern, and the electric field shielding pattern are overlapped each other.

9. The thin film transistor array substrate of claim 1, further comprising a light emitting device connected to the driving thin film transistor,
wherein light emitting device includes:
an anode electrode connected to the second drain electrode of the driving thin film transistor;
a cathode electrode corresponding to the anode electrode; and
a light emitting layer between the anode electrode and the cathode electrode.
